(19) United States
(12) Patent Application Publication
(10) Pub. No.: US 2023/0395668 A1
(43) Pub. Date: Dec. 7, 2023

(54) SEMICONDUCTOR DEVICE WITH DEEP SILICIDE FILM

(71) Applicant: SAMSUNG ELECTRONICS CO., LTD., Suwon-si (KR)

(72) Inventors: Su Jin JUNG, Suwon-si (KR); Jin Bum KIM, Suwon-si (KR); In Gyu JANG, Suwon-si (KR)

(21) Appl. No.: 18/296,329

(22) Filed: Apr. 5, 2023

(30) Foreign Application Priority Data
Jun. 7, 2022 (KR) 10-2022-0068662

(51) Int. Cl. H01L 29/417; H01L 29/06; H01L 29/775; H01L 29/786; H01L 29/66; H01L 29/423

(52) U.S. Cl. CPC H01L 29/41733; H01L 29/0653; H01L 29/775; H01L 29/78696; H01L 29/66553; H01L 29/0673; H01L 29/42392

(57) ABSTRACT

A semiconductor device includes a substrate; an active pattern disposed on the substrate and extending in a first direction; a plurality of gate structures, wherein the plurality of gate structures is disposed on the active pattern and arranged in the first direction, wherein each of the plurality of gate structures includes a gate electrode and a gate insulating film, and wherein the gate electrode extends in a second direction; a source/drain pattern disposed between adjacent gate structures of the plurality of gate structures; a source/drain contact connected to the source/drain pattern; and a contact silicide film disposed between the source/drain pattern and the source/drain contact, wherein the contact silicide film includes a bowl region that wraps a lower portion of the source/drain contact, and a protruding region that protrudes from the bowl region of the contact silicide film.

### CROSS-REFERENCE TO RELATED APPLICATION

This U.S. non-provisional application claims priority under 35 USC § 119 to Korean Patent Application No. 10-2022-0068662 filed on Jun. 7, 2022 in the Korean Intellectual Property Office, the disclosure is incorporated by reference herein in its entirety.

### TECHNICAL FIELD

Embodiments of the present disclosure relate to a semiconductor device. More particularly, embodiments of the present disclosure relate to a semiconductor device with a deep silicide film.

### DISCUSSION OF THE RELATED ART

Electronic devices include several constituent components, which may be referred to as semiconductor devices. Such devices include memory and memory systems, processors, display panels, touch panels, and the like. Recent consumer demand has driven the development of electronic devices with increased space utilization and portability. To implement these smaller devices, technologies such as multi gate transistors have been developed and used.

A multi-gate transistor includes a multi-channel active pattern, or a silicon body, with a fin or nanowire shape. The transistor is formed on a substrate, and further includes a gate which contacts the multi-channel active pattern. Additional layers may be added to increase the number of gates without increasing the 2D footprint of the semiconductor device.

### SUMMARY

Embodiments of the present disclosure include a semiconductor device capable of reducing the contact resistance between a source/drain and a contact, thereby increasing performance and reliability of the device.

A semiconductor device according to embodiments of the present disclosure includes a substrate; an active pattern disposed on the substrate and that extends in a first direction; a plurality of gate structures, wherein the plurality of gate structures is disposed on the active pattern and arranged in the first direction, wherein each gate structure of the plurality of gate structures includes a gate electrode and a gate insulating film, and wherein the gate electrode extends in a second direction; a source/drain pattern disposed between adjacent gate structures of the plurality of gate structures; a source/drain contact connected to the source/drain pattern; and a contact silicide film disposed between the source/drain pattern and the source/drain contact, wherein the contact silicide film includes a bowl region that wraps a lower portion of the source/drain contact, and a protruding region that protrudes from the bowl region of the contact silicide film in a third direction, wherein the third direction is orthogonal to the first and second directions.

A semiconductor device according to embodiments of the present disclosure includes an active pattern which includes a lower pattern which extends in a first direction, and wherein the active pattern includes a plurality of sheet patterns, wherein each of the plurality of sheet patterns extends in a second direction, and is spaced apart from the lower pattern in a third direction; a plurality of gate structures arranged in the first direction and disposed on the active pattern, wherein each of the plurality of gate structures includes a gate electrode and a gate insulating film, the gate electrode that extends in a second direction; a source/drain pattern disposed between adjacent gate structures of the plurality of gate structures and connected to the plurality of sheet patterns; a source/drain contact connected to the source/drain pattern; and a contact silicide film disposed between the source/drain pattern and the source/drain contact, wherein, as apparent from a cross-sectional view, the contact silicide film includes a protruding region, and includes a first bowl region and a second bowl region, wherein the first bowl region and the second bowl region each branch from the protruding region of the contact silicide film, the first bowl region of the contact silicide film and the second bowl region of the contact silicide film each extend in the third direction, and wherein the source/drain contact is disposed between the first bowl region of the contact silicide film and the second bowl region of the contact silicide film.

A semiconductor device according to embodiments of the present disclosure includes a substrate; a first active pattern including a first lower pattern and a plurality of first sheet patterns spaced apart from the first lower pattern in a vertical direction corresponding to a thickness direction of the substrate; a second active pattern including a second lower pattern and a plurality of second sheet patterns spaced apart from the second lower pattern in the vertical direction; a plurality of first gate structures disposed on the first lower pattern and arranged in a first horizontal direction; a plurality of second gate structures disposed on the second lower pattern and arranged in the first horizontal direction; a first source/drain pattern disposed between adjacent gate structures of the first gate structures, and wherein the first source/drain pattern comprises n-type impurities; a second source/drain pattern disposed between adjacent gate structures of the second gate structures, and wherein the second source/drain pattern comprises p-type impurities; a first source/drain contact connected to the first source/drain pattern; a second source/drain contact connected to the second source/drain pattern; a first contact silicide film disposed between the first source/drain pattern and the first source/drain contact; a second contact silicide film disposed between the second source/drain pattern and the second source/drain contact; and a first epitaxial air gap disposed in the first source/drain pattern, wherein the first epitaxial air gap contacts the first contact silicide film, and wherein the first contact silicide film includes a bowl region which extends along a profile of the first source/drain contact, and a protruding region which protrudes from the bowl region of the first contact silicide film in the vertical direction.

### BRIEF DESCRIPTION OF THE DRAWINGS

FIG. 1 is a plan view of a semiconductor device according to some embodiments of the present disclosure.

FIG. 2 is a cross-sectional view taken along A-A of FIG. 1.

FIG. 3 is a cross-sectional view taken along B-B of FIG. 1.

FIG. 4 is a cross-sectional view taken along C-C of FIG. 1.

FIG. 5 shows a first contact silicide film of FIG. 2 in a three-dimensional manner.

FIG. 6 is an enlarged view of a portion P of FIG. 2.

FIG. 7 is a diagram of a semiconductor device according to some embodiments of the present disclosure.

FIG. 8 is a diagram of a semiconductor device according to some embodiments of the present disclosure.

FIG. 9 is a diagram of a semiconductor device according to some embodiments of the present disclosure.

FIG. 10 is a diagram of a semiconductor device according to some embodiments of the present disclosure.

FIG. 11 is a diagram of a semiconductor device according to some embodiments of the present disclosure.

FIG. 12 is a diagram of a semiconductor device according to some embodiments of the present disclosure.

FIG. 13 is a diagram of a semiconductor device according to some embodiments of the present disclosure.

FIG. 14 is a diagram of a semiconductor device according to some embodiments of the present disclosure.

FIGS. 15 and 16 are diagrams of a semiconductor device according to some embodiments of the present disclosure.

FIGS. 17 and 18 are diagrams of a semiconductor device according to some embodiments of the present disclosure.

FIG. 19 is an plan view of a semiconductor device according to some embodiments of the present disclosure.

FIG. 20 is a cross-sectional view taken along a line D-D of FIG. 19.

### DETAILED DESCRIPTION

The following will describe embodiments of a semiconductor device. Although drawings of a semiconductor device according to some embodiments show a fin-shaped transistor (FinFET) including a channel region of a fin-shaped pattern shape, a transistor including a nanowire or a nanosheet, and a MBCFET™ (Multi-Bridge Channel Field Effect Transistor) as an example, the embodiments are not limited thereto. A semiconductor device according to some embodiments may include a tunneling transistor (tunneling FET) or a three-dimensional (3D) transistor. The semiconductor device according to some embodiments may include a planar transistor. In addition, embodiments of the present disclosure may be applied to and include transistors based on two-dimensional materials (2D material based FETs) and a heterostructure thereof. The semiconductor device according to some embodiments may also include a bipolar junction transistor, a laterally diffused metal oxide semiconductor (LDMOS), or the like.

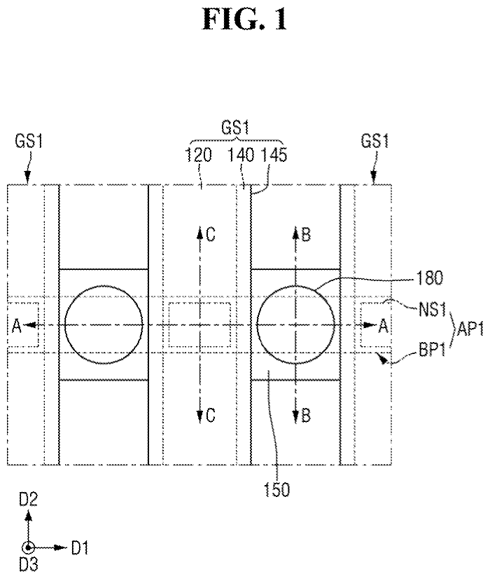

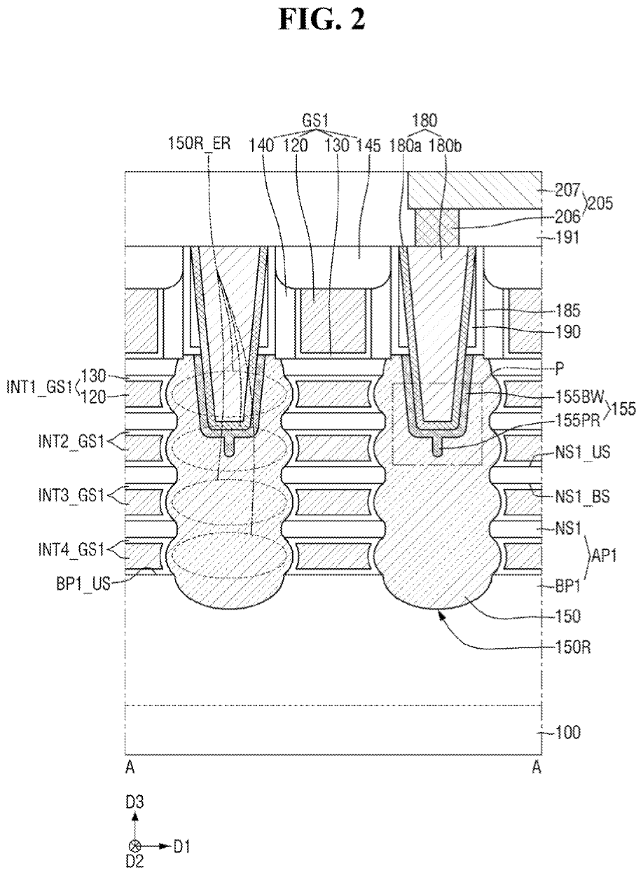

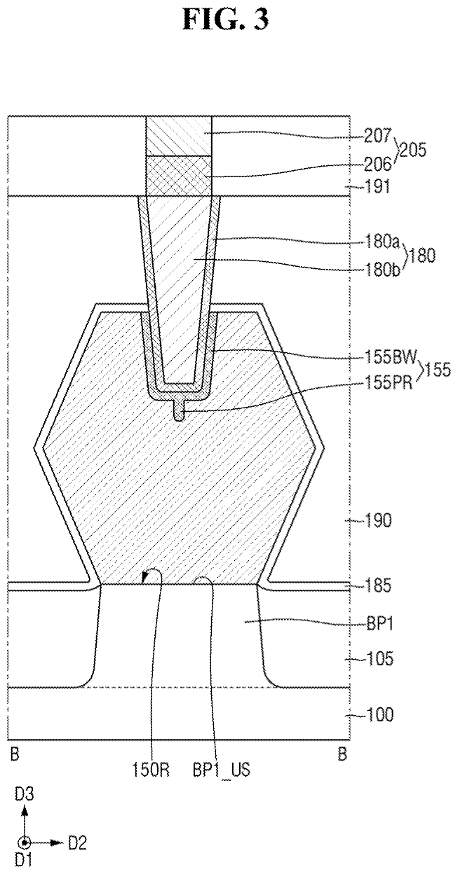

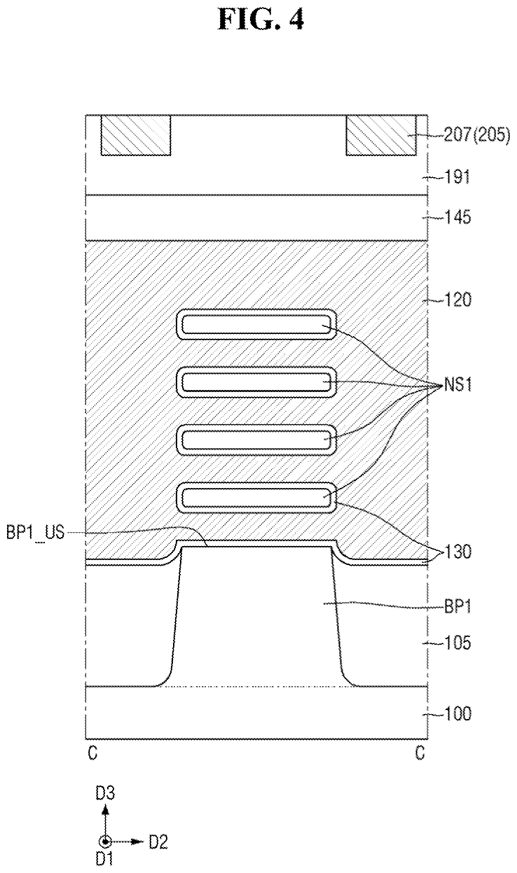

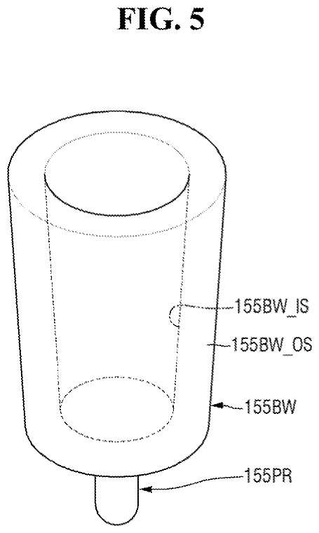

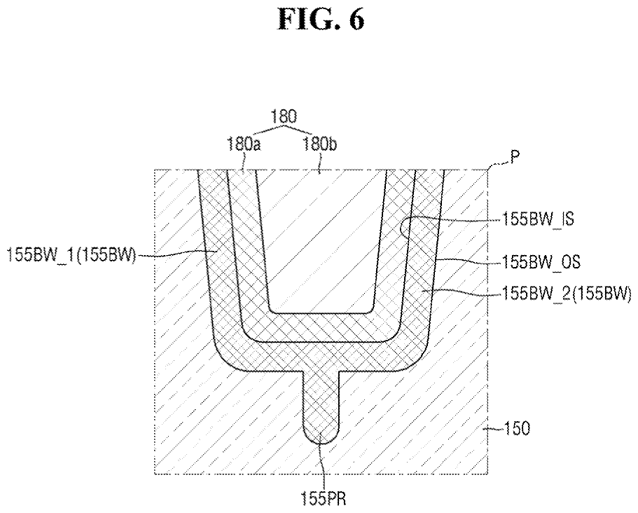

A semiconductor device according to some embodiments will be described with reference to FIGS. 1 to 6. FIG. 1 is an exemplary plan view of a semiconductor device according to some embodiments of the present disclosure. FIG. 2 is a cross-sectional view taken along A-A of FIG. 1. FIG. 3 is a cross-sectional view taken along B-B of FIG. 1. FIG. 4 is a cross-sectional view taken along C-C of FIG. 1. FIG. 5 shows a first contact silicide film of FIG. 2 in a three-dimensional manner. FIG. 6 is an enlarged view of a portion P of FIG. 2.

Referring to FIGS. 1 to 6, a semiconductor device according to some embodiments includes a first active pattern AP1, a plurality of first gate structures GS1, a first source/drain pattern 150, and a first source/drain contact 180.

The substrate 100 may be bulk silicon or silicon-on-insulator (SOI). In some embodiments, the substrate 100 is a silicon substrate, and may include, but is not necessarily limited to, silicon germanium, SGOI (silicon germanium on insulator), indium antimonide, lead tellurium compounds, indium arsenic, indium phosphide, gallium arsenide or gallium antimonide.

A first active pattern AP1 may be disposed on the substrate 100. The first active pattern AP1 may extend long in a first direction D1. In one example, the first active pattern AP1 is disposed in a region in which an NMOS is later formed. In another example, the first active pattern AP1 is disposed in a region in which a PMOS is later formed. The following will describe an example in which the first active pattern AP1 is disposed in a region in which the NMOS is formed. However, the description herein may be applied to examples that include the PMOS.

The first active pattern AP1 may be a multi-channel activity pattern. The first active pattern AP1 may include a first lower pattern BP1 and a plurality of first sheet patterns NS1.

The first lower pattern BP1 is disposed on the substrate 100. The first lower pattern BP1 may protrude from the substrate 100. The first lower pattern BP1 may extend in the first direction D1.

A plurality of first sheet patterns NS1 is disposed on an upper surface BP1_US of the first lower pattern. Each first sheet pattern of the NS1 of plurality of first sheet patterns NS1 may be spaced apart from the first lower pattern BP1 in a third direction D3.

Each first sheet pattern NS1 includes an upper surface NS1_US and a lower surface NS1_BS. The upper surface NS1_US of the first sheet pattern is opposite to the lower surface NS1_BS of the first sheet pattern in the third direction D3. The third direction D3 may be a direction that intersects the first direction D1 and the second direction D2. For example, the third direction D3 may be orthogonal with respect to a 2D plane formed by the first direction D1 and the second direction D2. For example, the third direction D3 may be a thickness direction of the substrate 100. Although four first sheet patterns NS1 are shown as being arranged in the third direction D3, such an arrangement is provided as an example and embodiments of the present disclosure are not necessarily limited thereto.

The first lower pattern BP1 may be formed by etching a portion of the substrate 100, and may include an epitaxial layer that is grown from the substrate 100. The first lower pattern BP1 may include silicon or germanium, which is an elemental semiconductor material. In some embodiments, the first lower pattern BP1 includes a compound semiconductor, and may include, for example, a group IV-IV compound semiconductor or a group III-V compound semiconductor.

The group IV-IV compound semiconductor may be a binary compound or a ternary compound including at least two or more of carbon (C), silicon (Si), germanium (Ge) and tin (Sn), or a compound obtained by doping these elements with a group IV element.

The group III-V compound semiconductor may be one of a binary compound, a ternary compound or a quaternary compound formed by combining at least one of aluminum (Al), gallium (Ga) and indium (In) as a group III element with one of phosphorus (P), arsenic (As) and antimony (Sb) as a group V element.

The first sheet pattern NS1 may include one of silicon or germanium, which are elemental semiconductor materials, a group IV-IV compound semiconductor, or a group III-V compound semiconductor. Each first sheet pattern NS1 may include the same material as the first lower pattern BP1, or may include a different material from the first lower pattern BP1.

In a semiconductor device according to some embodiments, the first lower pattern BP1 may be a silicon lower pattern including silicon, and the first sheet pattern NS1 may be a silicon sheet pattern including silicon.

A width of the first sheet pattern NS1 in the second direction D2 may increase or decrease proportionally to a change in the width of the first lower pattern BP1 in the second direction D2. For example, with particular reference to FIG. 4, if one embodiment of the semiconductor device includes a first lower pattern BP1 with increased width, then one or more of the first sheet patterns NS1 may also have increased width.

Although FIG. 4 illustrates an example in which the first sheet patterns NS1 stacked in the third direction D3 each have about the same width in the second direction D2, embodiments of the present disclosure are not necessarily limited thereto. In some cases, the width in the second direction D2 of each of the first sheet patterns NS1 stacked in the third direction D3 may decrease with increasing distance from the first lower pattern BP1.

A field insulating film 105 may be formed on the substrate 100. The field insulating film 105 may be disposed on the side walls of the first lower pattern BP1. The field insulating film 105 is not disposed on the upper surface BP1_US of the first lower pattern.

In some embodiments, the field insulating film 105 entirely covers the side walls of the first lower pattern BP1. In some embodiments, the field insulating film 105 may partially cover the side walls of the first lower pattern BP1. In such embodiments, a portion of the first lower pattern BP1 protrudes from the upper surface of the field insulating film 105 in the third direction D3.

Each first sheet pattern NS1 is disposed higher than the upper surface of the field insulating film 105. The field insulating film 105 may include, for example, an oxide film, a nitride film, an oxynitride film or a combination thereof. Although the field insulating film 105 is shown as a single film, this is only one embodiment and embodiments of the present disclosure are not necessarily limited thereto.

A plurality of first gate structures GS1 are be disposed on the substrate 100. Each first gate structure GS1 may extend in the second direction D2. The first gate structures GS1 may be spaced apart in (e.g., arranged) the first direction D1. The first gate structures GS1 may be adjacent to each other in the first direction D1. For example, a first gate structure GS1 may be disposed on both sides of the first source/drain pattern 150 in the first direction D1.

The first gate structure GS1 may be disposed on the first active pattern AP1. The first gate structure GS1 may intersect the first active pattern AP1.

The first gate structure GS1 may intersect the first lower pattern BP1. The first gate structure GS1 may wrap the respective first sheet patterns NS1. For example, the first gate structure GS1 may surround or at least partially surround first sheet patterns NS1.

The first gate structure GS1 may include, for example, a first gate electrode 120, a first gate insulating film 130, a first gate spacer 140, and a first gate capping pattern 145.

The first gate structure GS1 may include a plurality of inner gate structures INT1_GS1, INT2_GS1, INT3_GS1, and INT4_GS1. Each of the plurality of inner gate structures may be arranged in the third direction, and disposed between adjacent first sheet patterns of the first sheet patterns NS1, and between the first lower pattern BP1 and the first sheet pattern NS1. The inner gate structures INT1_GS1, INT2_GS1, INT3_GS1, and INT4_GS1 may be disposed between the upper surface BP1_US of the first lower pattern and the lower surface NS1_BS of the first lowermost sheet pattern, and between the upper surface NS1_US of the first sheet pattern and the lower surface NS1_BS of the first sheet pattern facing in the third direction D3.

The number of inner gate structures may correspond to the number of first sheet patterns NS1 included in the first active pattern AP1. For example, the embodiment shown in the figures includes four first sheet patterns NS1 included in the first active pattern AP1, and the corresponding number of inner gate structures INT1_GS1, INT2_GS1, INT3_GS1, and INT4_GS1 is four, i.e., the same as the number of first sheet patterns NS1. Since the first active pattern AP1 includes a plurality of first sheet patterns NS1, the first gate structure GS1 may include a plurality of inner gate structures.

The inner gate structures INT1_GS1, INT2_GS1, INT3_GS1, and INT4_GS1 contact the upper surface BP1_US of the first lower pattern, the upper surface NS1_US of the first sheet pattern, and the lower surface NS1_BS of the first sheet pattern. In some embodiments of the semiconductor device, the inner gate structures INT1_GS1, INT2_GS1, INT3_GS1, and INT4_GS1 also contact a first source/drain pattern 150 which will be described below. For example, the inner gate structures INT1_GS1, INT2_GS1, INT3_GS1, and INT4_GS1 may be in direct contact with the first source/drain pattern 150.

The following description will be provided using a case where the number of inner gate structures INT1_GS1, INT2_GS1, INT3_GS1, and INT4_GS1 is four. The first gate structure GS1 may include a first inner gate structure INT1_GS1, a second inner gate structure INT2_GS1, a third inner gate structure INT3_GS1, and a fourth inner gate structure INT4_GS1. The first inner gate structure INT1_GS1, the second inner gate structure INT2_GS1, the third inner gate structure INT3_GS1, and the fourth inner gate structure INT4_GS1 may be sequentially disposed on the first lower pattern BP1, e.g., as shown in the embodiment illustrated by FIG. 2.

The fourth inner gate structure INT4_GS1 may be disposed between the first lower pattern BP1 and the first sheet pattern NS1. In an embodiment, the fourth inner gate structure INT4_GS1 is disposed at the lowermost part (e.g., closest to the substrate 100) among the inner gate structures INT1_GS1, INT2_GS1, INT3_GS1 and INT4_GS1, and may be referred to as the lowermost inner gate structure.

The first inner gate structure INT1_GS1, the second inner gate structure INT2_GS1, and the third inner gate structure INT3_GS1 may be disposed between adjacent first sheet patterns of the first sheet patterns NS1 and arranged vertically, e.g. arranged in the third direction D3. The first inner gate structure INT1_GS1 may be disposed in uppermost portion of the semiconductor device with respect to the inner gate structures INT1_GS1, INT2_GS1, INT3_GS1, and INT4_GS1. For example, the first inner gate structure INT1_GS1 may be disposed the furthest from the substrate 100 and may be referred to as the uppermost inner gate structure. The second inner gate structure INT2_GS1 and the third inner gate structure INT3_GS1 are disposed between the first inner gate structure INT1_GS1 and the fourth inner gate structure INT4_GS1.

The inner gate structures INT1_GS1, INT2_GS1, INT3_GS1, and INT4_GS1 include a first gate electrode 120 and a first gate insulating film 130. The inner gate structures INT1_GS1, INT2_GS1, INT3_GS1, and INT4_GS1 are disposed between adjacent first sheet patterns NS1, and between the first lower pattern BP1 and the first sheet pattern NS1.

The following description applies to an embodiment illustrated in FIG. 2, which is a cross-sectional view that results from a cut in the first direction D1. In this example, the width of the first inner gate structure INT1_GS1 is the same as or similar to the width of the second inner gate structure INT2_GS1 and the width of the third inner gate structure INT3_GS1. The width of the fourth inner gate structure INT4_GS1 is the same as or similar to the width of the third inner gate structure INT3_GS1.

In another example, the width of the fourth inner gate structure INT4_GS1 is greater than the width of the third inner gate structure INT3_GS1. In an example, the width of the first inner gate structure INT1_GS1 may be the same as the width of the second inner gate structure INT2_GS1 and the width of the third inner gate structure INT3_GS1.

An example of the second inner gate structure INT2_GS1 will now be described. The width of the second inner gate structure INT2_GS1 may be measured at the midpoint between the upper surface NS1_US of the first sheet pattern and the lower surface NS1_BS of the first sheet pattern, which face each other in the third direction D3.

A first gate electrode 120 may be formed on the first lower pattern BP1. The first gate electrode 120 may intersect the first lower pattern BP1. The first gate electrode 120 may wrap the first sheet pattern NS1. For example, the first gate electrode 120 may surround or at least partially surround the first sheet pattern NS1.

A portion of the first gate electrode 120 may be disposed between adjacent first sheet patterns of the first sheet patterns NS1. When the first sheet pattern NS1 includes a first lower sheet pattern and a first upper sheet pattern adjacent to each other in the third direction D3, a portion of the first gate electrode 120 may be disposed between the upper surface NS1_US of first lower sheet pattern and the lower surface NS1_BS of the first upper sheet pattern. In some embodiments, a portion of the first gate electrode 120 is additionally disposed between the upper surface BS1_US of the first lower pattern and the lower surface NS1_BS of the first lowermost sheet pattern.

The first gate electrode 120 may include at least one of a metal, a metal alloy, a conductive metal nitride, a metal silicide, a doped semiconductor material, a conductive metal oxide, or a conductive metal oxynitride. The first gate electrode 120 may include, but is not necessarily limited to, for example, at least one of titanium nitride (TiN), tantalum carbide (TaC), tantalum nitride (TaN), titanium silicon nitride (TiSiN), tantalum silicon nitride (TaSiN), tantalum titanium nitride (TaTiN), titanium aluminum nitride (TiAlN), tantalum aluminum nitride (TaAlN), tungsten nitride (WN), ruthenium (Ru), titanium aluminum (TiAl), titanium aluminum carbonitride (TiAlC—N), titanium aluminum carbide (TiAlC), titanium carbide (TiC), tantalum carbonitride (TaCN), tungsten (W), aluminum (Al), copper (Cu), cobalt (Co), titanium (Ti), tantalum (Ta), nickel (Ni), platinum (Pt), nickel platinum (Ni—Pt), niobium (Nb), niobium nitride (NbN), niobium carbide (NbC), molybdenum (Mo), molybdenum nitride (MoN), molybdenum carbide (MoC), tungsten carbide (WC), rhodium (Rh), palladium (Pd), iridium (Ir), osmium (Os), silver (Ag), gold (Au), zinc (Zn), vanadium (V), and combinations thereof. The conductive metal oxides and conductive metal oxynitride may include, but are not necessarily limited to, oxidized forms of the aforementioned materials.

The first gate electrode 120 may be disposed on both sides of a first source/drain pattern 150, which will be described below. For example, the first gate structure GS1 may be disposed on both sides of the first source/drain pattern 150 in the first direction D1.

The first gate electrodes 120 disposed on both sides of the first source/drain pattern 150 may be normal gate electrodes which are used as gates of transistors. In some embodiments, the first gate electrode 120 disposed on one side of the first source/drain pattern 150 is used as a gate of a transistor, while the first gate electrode 120 disposed on the other side of the first source/drain pattern 150 is a dummy gate electrode.

The first gate insulating film 130 may extend along the upper surface of the field insulating film 105 and the upper surface BP1_US of the first lower pattern. The first gate insulating film 130 may surround or wrap the plurality of first sheet patterns NS1. The first gate insulating film 130 may be disposed along the periphery of the first sheet pattern NS1.

The first gate electrode 120 is disposed on the first gate insulating film 130. The first gate insulating film 130 is disposed between the first gate electrode 120 and the first sheet pattern NS1. A portion of the first gate insulating film 130 may be disposed between the first sheet patterns NS1 adjacent in the third direction D3, and between the first lower pattern BP1 and the first sheet pattern NS1.

The first gate insulating film 130 may include one of silicon oxide, silicon-germanium oxide, germanium oxide, silicon oxynitride, silicon nitride, or a high dielectric constant material that has a higher dielectric constant than silicon oxide. The high dielectric constant material may include, for example, one of boron nitride, hafnium oxide, hafnium silicon oxide, hafnium aluminum oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, lead zinc niobate or a combination thereof.

Although the first gate insulating film 130 is shown as a single film, embodiments of the present disclosure are not necessarily limited thereto. The first gate insulating film 130 may include multiple films. The first gate insulating film 130 may include an interface layer disposed between the first sheet pattern NS1 and the first gate electrode 120, and a high dielectric constant insulating film.

A semiconductor device according to some embodiments may include an NC (Negative Capacitance) FET that uses a negative capacitor. For example, the first gate insulating film 130 may include a ferroelectric material film that has ferroelectric properties, and a paraelectric material film that has paraelectric properties.

In some embodiments, the ferroelectric material film has a negative capacitance, and the paraelectric material film has a positive capacitance. For example, if two or more capacitors are connected in series and the capacitance of each capacitor has a positive value, an aggregate capacitance (e.g., an overall or total capacitance) may decrease from the capacitance of each of the individual capacitors. On the other hand, if at least one of the capacitances of two or more capacitors connected in series has a negative value, an aggregate capacitance may be greater than an absolute value of each of the individual capacitances, while having a positive value.

When a ferroelectric material film that has the negative capacitance and a paraelectric material film that has the positive capacitance are connected in series, the aggregate capacitance of the ferroelectric material film and the paraelectric material film connected in series may increase. By the use of the increased aggregate capacitance value, a transistor including the ferroelectric material film may have a subthreshold swing (SS) below 60 mV/decade at room temperature.

A ferroelectric material film may include hafnium oxide, hafnium zirconium oxide, barium strontium titanium oxide, barium titanium oxide, lead zirconium titanium oxide, or a combination thereof. In an example, the hafnium zirconium oxide may be obtained by doping hafnium oxide with zirconium (Zr). In an example, the hafnium zirconium oxide may be a compound of hafnium (Hf), zirconium (Zr), and oxygen (O).

A ferroelectric material film may further include a dopant. For example, the dopant may include at least one of aluminum (Al), titanium (Ti), niobium (Nb), lanthanum (La), yttrium (Y), magnesium (Mg), silicon (Si), calcium (Ca), cerium (Ce), dysprosium (Dy), erbium (Er), gadolinium (Gd), germanium (Ge), scandium (Sc), strontium (Sr), or tin (Sn). The type of dopant included in the ferroelectric material film may vary, depending on which type of ferroelectric material is included in the ferroelectric material film.

When a ferroelectric material film includes hafnium oxide, the dopant included in the ferroelectric material film may include gadolinium (Gd), silicon (Si), zirconium (Zr), aluminum (Al), yttrium (Y), or a combination thereof.

When the dopant is aluminum (Al), the ferroelectric material film may include 3 to 8 at % (atomic %) aluminum. In an example, a ratio of the dopant may be a ratio of aluminum to the sum of hafnium and aluminum.

When the dopant is silicon (Si), the ferroelectric material film may include 2 to 10 at % silicon. When the dopant is yttrium (Y), the ferroelectric material film may include 2 to 10 at % yttrium. When the dopant is gadolinium (Gd), the ferroelectric material film may include 1 to 7 at % gadolinium. When the dopant is zirconium (Zr), the ferroelectric material film may include 50 to 80 at % zirconium.

A paraelectric material film may include a silicon oxide, a metal oxide that has a high dielectric constant, or both. The metal oxide included in the paraelectric material film may include, for example, but not limited to, at least one of hafnium oxide, zirconium oxide, and aluminum oxide.

The ferroelectric material film and the paraelectric material film may include the same or one or more of the same materials. In some examples, the ferroelectric material film has the ferroelectric properties, while the paraelectric material film does not have the ferroelectric properties. For example, when the ferroelectric material film and the paraelectric material film include hafnium oxide, a crystal structure of hafnium oxide included in the ferroelectric material film is different from a crystal structure of hafnium oxide included in the paraelectric material film.

The ferroelectric material film may have a thickness which enables the ferroelectric properties. The thickness of the ferroelectric material film may be, for example, but is not necessarily limited to, 0.5 to 10 nm. Since a critical thickness that exhibits the ferroelectric properties may vary for each ferroelectric material, the thickness of the ferroelectric material film may vary depending on the ferroelectric material.

As an example, the first gate insulating film 130 may include one ferroelectric material film. As another example, the first gate insulating film 130 may include a plurality of ferroelectric material films spaced apart from each other. In a multi-film structure, for example, the first gate insulating film 130 may have a stacked film structure in which the plurality of ferroelectric material films and the plurality of paraelectric material films are alternately stacked.

The first gate capping pattern 140 may be disposed on the side wall of the first gate electrode 120. The first gate spacers 140 might not be disposed between the first lower pattern BP1 and the first sheet pattern NS1, and between the first sheet patterns NS1 adjacent in the third direction D3. In the semiconductor device according to some embodiments, the first gate spacers 140 may include only an outer spacer.

The first gate spacer 140 may include, for example, at least one of silicon nitride (SiN), silicon oxynitride (SiON), silicon oxide (SiO₂), silicon oxycarbonitride (SiOCN), silicon boronitride (SiBN), silicon oxyboronitride (SiOBN), silicon oxycarbide (SiOC), and combinations thereof. Although the first gate spacer 140 is illustrated as a single film, embodiments of the present disclosure are not necessarily limited thereto.

A first gate capping pattern 145 may be disposed on the first gate electrode 120 and the first gate spacer 140. An upper surface of the first gate capping pattern 145 may be disposed on the same plane as an upper surface of the first interlayer insulating film 190. In some embodiments, the first gate capping pattern 145 can be disposed between the first gate spacers 140.

The first gate capping pattern 145 may include one of silicon nitride (SiN), silicon oxynitride (SiON), silicon carbonitride (SiCN), silicon oxycarbonitride (SiOCN), or combinations thereof. The first gate capping pattern 145 may include a material that has an etch selectivity with respect to the interlayer insulating film 190.

The following will describe the first source/drain pattern 150. A first source/drain pattern 150 may be formed on the first active pattern AP1. The first source/drain pattern 150 may be disposed on the first lower pattern BP1. The first source/drain pattern 150 is connected to the first sheet pattern NS1. The first source/drain pattern 150 directly contacts the first sheet pattern NS1.

The first source/drain pattern 150 may be disposed adjacent to the side surface of the first gate structure GS1. The first source/drain pattern 150 may contact side surface(s) of one or more first gate structures GS1. The first source/drain patterns 150 may be disposed between the first gate structures GS1 adjacent to each other in the first direction D1. For example, the first source/drain patterns 150 may be disposed on both sides of the first gate structure GS1. In some embodiments, the first source/drain pattern 150 can be disposed on one side of the first gate structure GS1 and not disposed on the other side of the first gate structure GS1.

The first source/drain pattern 150 may be included in a source/drain of a transistor that uses the first sheet pattern NS1 as a channel region. The first source/drain pattern 150 may be disposed in a first source/drain recess 150R. The first source/drain pattern 150 may fill the source/drain recess 150R.

The first source/drain recess 150R extends in the third direction D3. The first source/drain recess 150R may be formed by a region between the first gate structures GS1 adjacent to each other in the first direction D1.

A bottom surface of the first source/drain recess 150R is defined by the first lower pattern BP1. The side walls of the first source/drain recess 150R may be defined by the first sheet pattern NS1 and the inner gate structures INT1_GS1, INT2_GS1, INT3_GS1, and INT4_GS1.

The inner gate structures INT1_GS1, INT2_GS1, INT3_GS1, and INT4_GS1 include side walls that connect the upper surfaces of the inner gate structures INT1_GS1, INT2_GS1, INT3_GS1, and INT4_GS1 to the lower surfaces of the inner gate structures INT1_GS1, INT2_GS1, INT3_GS1, and INT4_GS1. The side walls of the inner gate structures INT1_GS1, INT2_GS1, INT3_GS1, and INT4_GS1 may define a portion of the side walls of the first source/drain recess 150R.

An upper surface BP1_US of the first lower pattern BP1 may be defined as the interface between the first lower pattern BP1 and the first gate insulating film 130 that contacts the fourth inner gate structure INT4_GS1 and the first lower pattern BP1. In embodiments, a bottom surface of the first source/drain recess 150R is disposed lower than the upper surface BP1_US of the first lower pattern.

Side walls of the first source/drain recess 150R may have a wavy shape. This may be apparent in a cross-sectional view of the semiconductor device, such as the view illustrated in FIG. 2. The first source/drain recess 150R may include a plurality of first width extension regions 150R_ER. The width of the first source/drain pattern 150 may increase in each of the first width extension regions 150R_ER, so as to form a plurality of “bulges” arranged vertically in the third direction D3. Each first width extension region 150R_ER may be defined above the upper surface BP1_US of the first lower pattern.

The first width extension region 150R_ER may be formed between the first sheet patterns NS1 adjacent in the third direction D3. The first width extension region 150R_ER may be defined between the first lower pattern BP1 and the first sheet pattern NS1. The first width extension region 150R_ER may extend between the first sheet patterns NS1 adjacent in the third direction D3. The first width extension region 150R_ER may be defined between the inner gate structures INT1_GS1, INT2_GS1, INT3_GS1, and INT4_GS1 adjacent in the first direction D1.

Each first width extension region 150R_ER may include a portion whose width increases in the first direction D1 and a portion whose width decreases in the first direction D1 as a function of distance from the upper surface BP1_US of the first lower pattern. For example, the width of the first width extension region 150R_ER may increase and then decrease, with distance from the upper surface BP1_US of the first lower pattern.

In each first width expansion region 150R_ER, a point in which the width of the first width expansion region 150R_ER is maximum is located between the first sheet pattern NS1 and the first lower pattern BP1, or between adjacent first sheet patterns NS1.

The first source/drain pattern 150 may directly contact with the first sheet pattern NS1 and the first lower pattern BP1. The first gate insulating films 130 of the inner gate structures INT1_GS1, INT2_GS1, INT3_GS1, and INT4_GS1 may directly contact with the first source/drain pattern 150.

The first source/drain patterns 150 may include an epitaxial pattern. Some embodiments of the first source/drain patterns 150 are grown using an epitaxial process. The first source/drain pattern 150 includes a semiconductor material. The first source/drain pattern 150 may include, for example, silicon or germanium which is an elemental semiconductor material. Some embodiments of the first source/drain pattern 150 include a binary compound or a ternary compound including at least two or more of carbon (C), silicon (Si), germanium (Ge), and tin (Sn), or a compound obtained by doping these elements with a group IV element. For example, the first source/drain pattern 150 may include, but not limited to, silicon, silicon-germanium, silicon carbide, and the like.

The first source/drain pattern 150 may include impurities doped to the semiconductor material. For example, the first source/drain pattern 150 may include n-type impurities. The doped n-type impurities may include at least one of phosphorous (P), arsenic (As), antimony (Sb) and bismuth (Bi).

Although the first source/drain pattern 150 is shown to be a single film, embodiments of the present disclosure are not necessarily limited thereto. For example, the source/drain pattern 150 may be formed or grown in multiple stages with the same or different materials.

The source/drain etch stop film 185 may be disposed on the side walls of the first gate structure GS1, the upper surface of the first source/drain pattern 150, the side walls of the first source/drain pattern 150, and the upper surface of the field insulating film 105. The source/drain etch stop film 185 may include a material that has an etch selectivity with respect to a first interlayer insulating film 190, which will be described below.

The source/drain etch stop film 185 may include silicon nitride (SiN), silicon oxynitride (SiON), silicon oxycarbonitride (SiOCN), silicon boronitride (SiBN), silicon oxyboronitride (SiOBN), silicon oxycarbide (SiOC), or combinations thereof. In some embodiments, the source/drain etch stop film 185 is not formed.

The first interlayer insulating film 190 may be disposed on the source/drain etch stop film 185. The first interlayer insulating film 190 may be disposed on the first source/drain pattern 150. The first interlayer insulating film 190 might not cover the upper surface of the first gate capping pattern 145. For example, the upper surface of the first interlayer insulating film 190 may be disposed on the same plane as the upper surface of the first gate capping pattern 145.

The first interlayer insulating film 190 may include one of silicon oxide, silicon nitride, silicon oxynitride, a low dielectric constant material, or a combination thereof. The low dielectric constant material may include, but is not necessarily limited to, Fluorinated TetraEthylOrthoSilicate (FTEOS), Hydrogen SilsesQuioxane (HSQ), Bis-benzoCycloButene (BCB), TetraMethylOrthoSilicate (TMOS), OctaMethyleyCloTetraSiloxane (OMCTS), HexaMethylDiSiloxane (HMDS), TriMethylSilyl Borate (TMSB), DiAcetoxyDitertiaryButoSiloxane (DADBS), TriMethylSilil Phosphate (TMSP), PolyTetraFluoroEthylene (PTFE), TOSZ (Tonen SilaZen), FSG (Fluoride Silicate Glass), polyimide nanofoams such as polypropylene oxide, CDO (Carbon Doped silicon Oxide), OSG (Organo Silicate Glass), SiLK, Amorphous Fluorinated Carbon, silica aerogels, silica xerogels, mesoporous silica or combinations thereof.

The first source/drain contact 180 is disposed on the first source/drain pattern 150. The first source/drain contact 180 is connected to, e.g., electrically connected to, the first source/drain pattern 150. The first source/drain contact 180 passes through the first interlayer insulating film 190 and the source/drain etch stop film 185, and may be connected to the first source/drain pattern 150.

The first source/drain contacts 180 may include a first source/drain barrier film 180a and a first source/drain filling film 180b. The first source/drain filling film 180b is disposed on the first source/drain barrier film 180a.

The first source/drain barrier film 180a may include one of tantalum (Ta), tantalum nitride (TaN), titanium (Ti), titanium nitride (TiN), titanium silicon nitride (TiSiN), ruthenium (Ru), cobalt (Co), nickel (Ni), nickel boron (NiB), tungsten (W), tungsten nitride (WN), tungsten carbonitride (WCN), zirconium (Zr), zirconium nitride (ZrN), vanadium (V), vanadium nitride (VN), niobium (Nb), niobium nitride (NbN), platinum (Pt), iridium (Ir), rhodium (Rh), two-dimensional (2D) material, or a combination thereof. In the semiconductor device according to some embodiments, the two-dimensional material may be a metallic material and/or a semiconductor material. The two-dimensional (2D) material may include a 2D allotrope or a 2D compound, and may include, but is not necessarily limited to, one of graphene, molybdenum disulfide (MoS₂), molybdenum diselenide (MoSe₂), tungsten diselenide (WSe₂), tungsten disulfide (WS₂), or a combination thereof. However, the present disclosure does not necessarily limit the 2D materials that may be included in the semiconductor device to those mentioned above, and other 2D materials may be used.

The first source/drain filling film 180b may include one of aluminum (Al), tungsten (W), cobalt (Co), copper (Cu), ruthenium (Ru), silver (Ag), gold (Au), manganese (Mn), molybdenum (Mo), or a combination thereof. In some embodiments, the first source/drain contact 180 is formed of only a single film.

The first contact silicide film 155 is disposed between the first source/drain contact 180 and the first source/drain pattern 150. The first contact silicide film 155 wraps (e.g., partially surrounds) the first source/drain contact 180 that penetrates into the first source/drain pattern 150. The first contact silicide film 155 is in contact with the first source/drain contact 180 and the first source/drain pattern 150. For example, the first contact silicide film 155 may directly contact both the first source/drain contact 180 and the first source/drain pattern 150.

The first contact silicide film 155 may include a bowl region 155BW and a protruding region 155PR. The bowl region 155BW of the first contact silicide film is directly connected to the protruding region 155PR of the first contact silicide film. In some embodiments, the bowl region 155BW of the first contact silicide film is contiguously connected to the protruding region 155PR of the first contact silicide film, with no barrier or apparent line therebetween.

The protruding region 155PR of the first contact silicide film protrudes from the bowl region 155BW of the first contact silicide film in the third direction D3. The protruding region 155PR of the first contact silicide film protrudes from the bowl region 155BW of the first contact silicide film toward the first lower pattern BP1.

The bowl region 155BW of the first contact silicide film may wrap the first source/drain contact 180 that penetrates into the first source/drain pattern 150. For example, the bowl region 155BW of the first contact silicide film may surround lateral sides and a bottom surface of the first source/drain contact 180. In some embodiments, the bowl region 155BW of the first contact silicide film may substantially surround the bottom surface of the first source/drain contact 180 and a relatively small portion of the lateral sides, thereby wrapping a “tip” of the first source/drain contact 180. The protruding region 155PR of the first contact silicide film may extend from the lowest part of the first source/drain contact 180 toward the first lower pattern BP1 in the third direction D3.

With reference to FIGS. 5 and 6, the bowl region 155BW of the first contact silicide film may include an inner side surface 155BW_IS and an outer side surface 155BW_OS. The inner side surface 155BW_IS of the bowl region of the first contact silicide film is in contact with the first source/drain contact 180. The outer side surface 155 BW_OS of the bowl region of the first contact silicide film is in contact with the first source/drain pattern 150.

The bowl region 155BW of the first contact silicide film may have a three-dimensional pocket shape. For example, the bowl region 155BW may be formed by the intersection of a larger and a smaller concentric cone, with an upper half of both cones removed to form the bottom of the bowl. The inner side surface 155BW_IS of the bowl region of the first contact silicide film and the outer side surface 155BW_OS of the bowl region of the first contact silicide film may each have a convex shape toward the substrate 100.

The protruding region 155PR of the first contact silicide film is directly connected to the outer side surface 155BW_OS of the bowl region of the first contact silicide film. The protruding region 155PR of the first contact silicide film may protrude in the third direction D3 from the outer side surface 155BW_OS of the bowl region of the first contact silicide film.

With reference to FIG. 1, the first contact silicide film 155 may include a first bowl region 155BW_1 and a second bowl region 155BW_2 that each branch from the protruding region 155PR of the first contact silicide film.

The first bowl region 155BW_1 of the first contact silicide film and the second bowl region 155BW_2 of the first contact silicide film may extend along a profile of the first source/drain contact 180. For example, first bowl region 155BW_1 of the first contact silicide film and the second bowl region 155BW_2 of the first contact silicide film may conform to a shape of the first source/drain contact 180. The first source/drain contact 180 may be disposed between the first bowl region 155BW_1 of the first contact silicide film and the second bowl region 155BW_2 of the first contact silicide film.

The first bowl region 155BW_1 of the first contact silicide film and the second bowl region 155BW_2 of the first contact silicide film may each extend in the third direction D3. The first bowl region 155BW_1 of the first contact silicide film and the second bowl region 155BW_2 of the first contact silicide film may be spaced apart from each other in the first direction D1.

As apparent from a cross-sectional view, the bowl region 155BW of the first contact silicide film may include a first end and a second end that form a boundary with the source/drain etch stop film 185. For example, the first end of the bowl region 155BW of the first contact silicide film and the second end of the bowl region 155BW of the first contact silicide film may be in direct contact with the source/drain etch stop film 185. The protruding region 155PR of the first contact silicide film may protrude toward the first lower pattern BP1 along a midline between the first end of the bowl region 155BW of the first contact silicide film and the second end of the bowl region 155BW of the first contact silicide film, towards the substrate 100.

The first contact silicide film 155 includes a metal silicide material. In an example, the metal silicide material includes the metal included in the first source/drain barrier film 180a. In another example, the metal silicide material includes another metal different from the first source/drain barrier film 180a.

A second interlayer insulating film 191 is disposed on the first interlayer insulating film 190. The second interlayer insulating film 191 may include silicon oxide, silicon nitride, silicon oxynitride, a low dielectric constant material, or a combination thereof.

The wiring structure 205 is disposed in the second interlayer insulating film 191. The wiring structure 205 may be connected with the first source/drain contact 180. The wiring structure 205 may include a wiring line 207 and a wiring via 206.

The figures illustrate the wiring line 207 and the wiring via 206 as separate components, but embodiments of the present disclosure are not necessarily limited thereto. In some embodiments, the wiring line 207 is formed after the wiring via 206 is formed. In some other embodiments, the wiring via 206 and the wiring line 207 are formed at the same time.

Although the figures illustrate the wiring line 207 as a single film and the wiring via 206 as a single film, embodiments of the present disclosure are not necessarily limited thereto. The wiring line 207 and the wiring via 206 may each include, for example, at least one of a metal, a metal alloy, conductive metal nitride, conductive metal carbide, conductive metal oxide, conductive metal carbonitride, and a two-dimensional (2D) material.

In some embodiments, the upper surface of the first source/drain contact 180 of the portion connected to the wiring structure 205 may be disposed on the same plane as the upper surface of the first source/drain contact 180 of the portion that is not connected to the wiring structure 205.

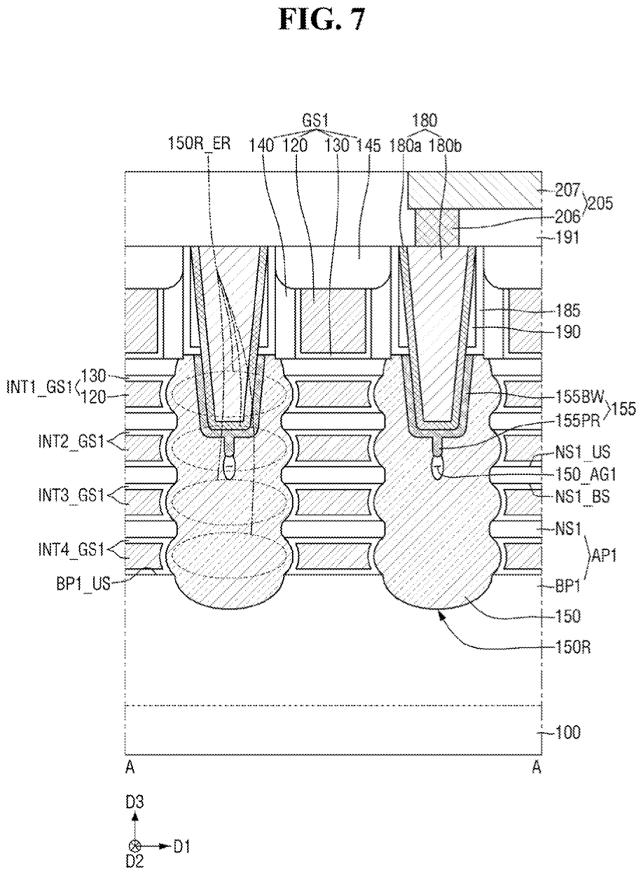

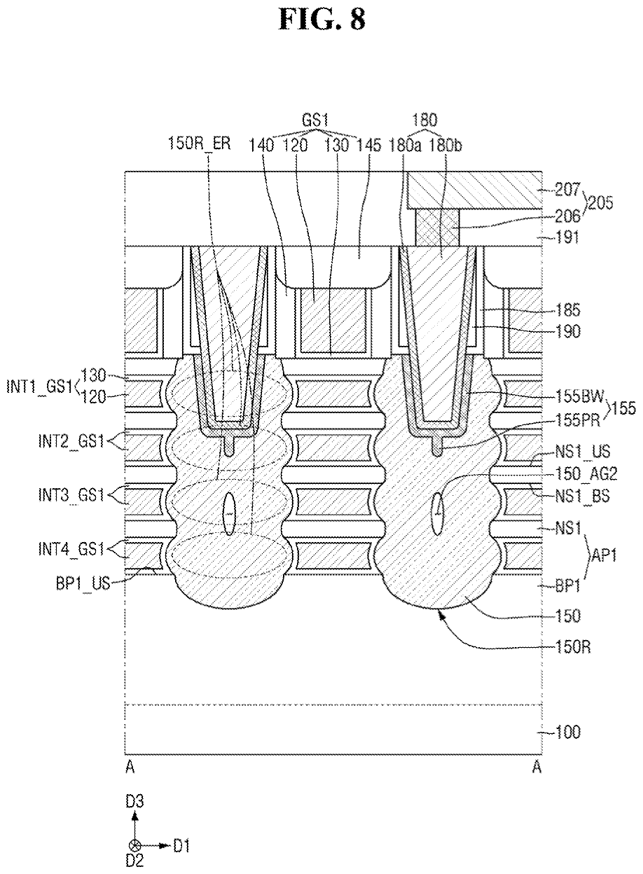

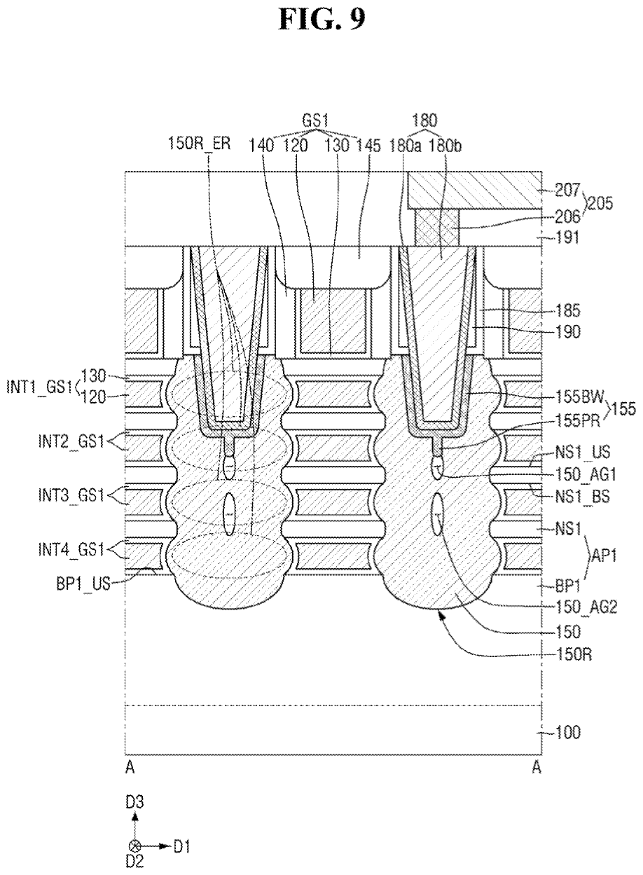

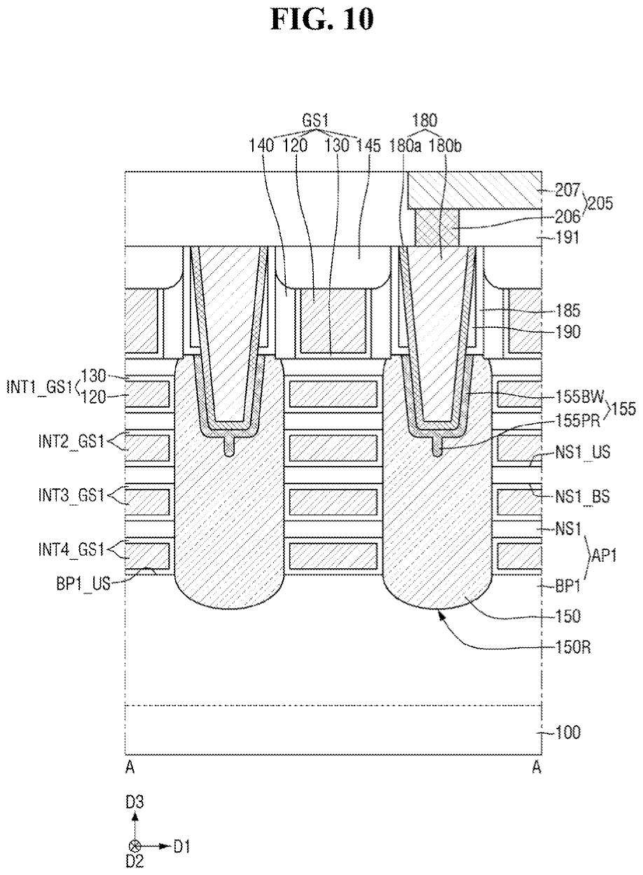

FIG. 7 is a diagram of a semiconductor device according to some embodiments of the present disclosure. FIG. 8 is a diagram of a semiconductor device according to some embodiments of the present disclosure. FIG. 9 is a diagram of a semiconductor device according to some embodiments of the present disclosure. FIG. 10 is a diagram of a semiconductor device according to some embodiments of the present disclosure.

Referring to FIG. 7, the semiconductor device according to some embodiments may include a first epitaxial air gap 150_AG1 disposed in the first source/drain pattern 150. The first epitaxial air gap 150_AG1 may be in direct contact with the first contact silicide film 155. The first epitaxial air gap 150_AG1 directly contact the protruding region 155PR of the first contact silicide film. The first epitaxial air gap 150_AG1 is disposed below the protruding region 155PR of the first contact silicide film/The first epitaxial air gap 150_AG1 may be surrounded by the first source/drain pattern 150 and the first contact silicide film 155.

Referring to FIG. 8, the semiconductor device according to some embodiments may include a second epitaxial air gap 150_AG2 disposed in the first source/drain pattern 150. In this example, the second epitaxial air gap 150_AG2 does not contact the first contact silicide film 155. The second epitaxial air gap 150_AG2 may be spaced apart from the protruding region 155PR of the first contact silicide film in the third direction D3.

A portion of the first source/drain pattern 150 may be disposed between the second epitaxial air gap 150_AG2 and the first contact silicide film 155. The second epitaxial air gap 150_AG2 may be surrounded by the first source/drain pattern 150.

Referring to FIG. 9, the semiconductor device according to some embodiments may include a first epitaxial air gap 150_AG1 and a second epitaxial air gap 150_AG2 disposed in the first source/drain pattern 150. The first epitaxial air gap 150_AG1 may be spaced apart from the second epitaxial air gap 150_AG2 in the third direction D3. The first epitaxial air gap 150_AG1 may directly contact the protruding region 155PR of the first contact silicide film. In this example, the second epitaxial air gap 150_AG2 does not contact the first contact silicide film 155. In some embodiments, the first epitaxial air gap 150_AG1 may be disposed in a first source/drain pattern 150 on one side of the first gate structure GS1, while the second epitaxial air gap 150_AG2 is disposed in another source/drain pattern 150 on the other side of the first gate structure GS1. In some embodiments, the first epitaxial air gap 150_AG1 is disposed in one or more of the first source/drain patterns 150 on a first side of the first gate structure GS1. In some embodiments, the second epitaxial air gap 150_AG2 is disposed in one or more of the first source/drain patterns 150 on a first side of the first gate structure GS1.

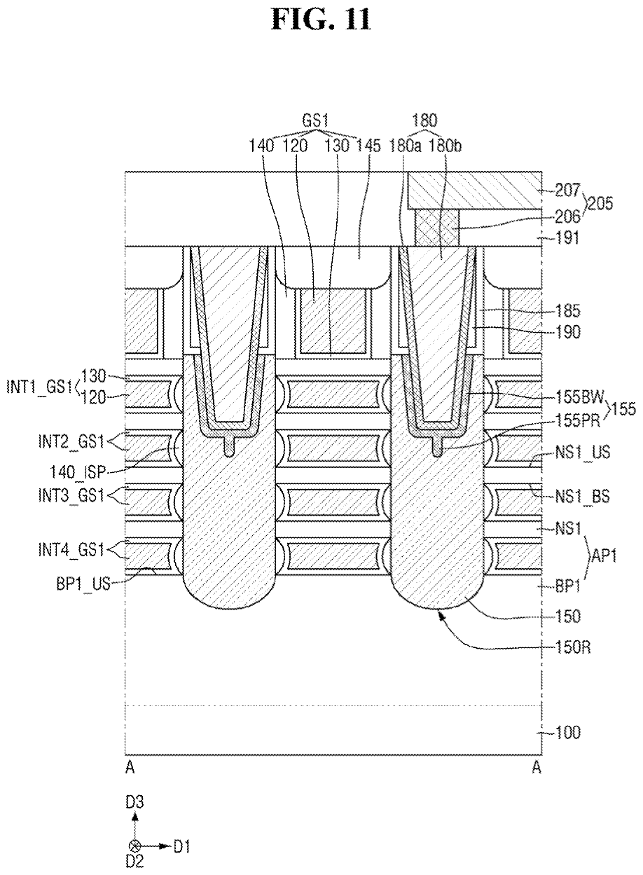

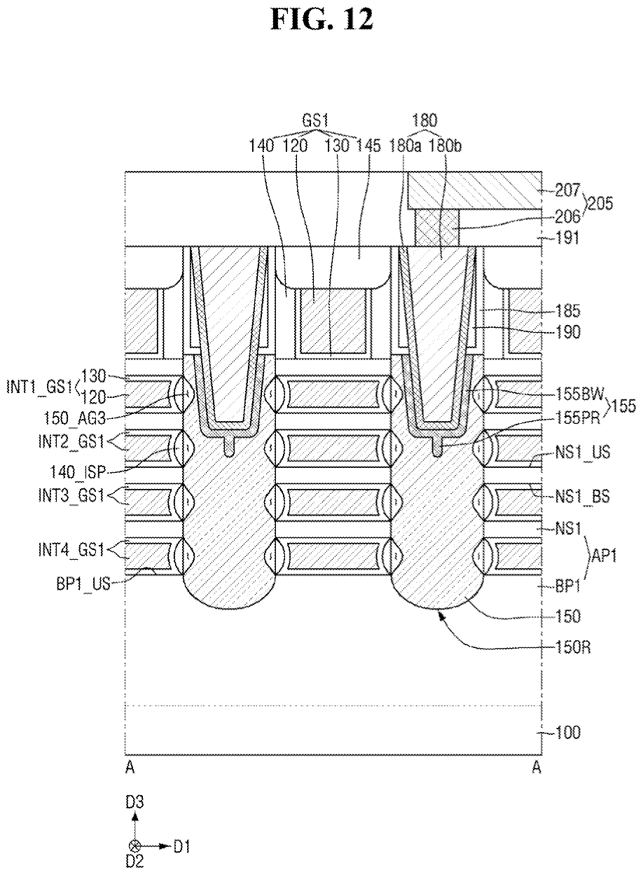

FIG. 10 is a diagram of a semiconductor device according to some embodiments of the present disclosure. FIG. 11 is a diagram of a semiconductor device according to some embodiments of the present disclosure. FIG. 12 is a diagram of a semiconductor device according to some embodiments of the present disclosure. For convenience of explanation, the explanation will focus on points different from those explained using FIGS. 1 to 6.

Referring to FIG. 10, in the semiconductor device according to some embodiments, the first source/drain recess 150R does not include a plurality of first width extension regions (e.g., 150R_ER of FIG. 2). In this example, the side walls of the first source/drain recess 150R do not have a wavy shape. In some embodiments, the width of the upper part of the side walls of the first source/drain recess 150R in the first direction D1 may decreases with distance from the first lower pattern BP1, thereby forming a conical shape.

FIG. 11 is a diagram of a semiconductor device according to some embodiments of the present disclosure. FIG. 12 is a diagram of a semiconductor device according to some embodiments of the present disclosure. Referring to FIGS. 11 and 12, in the semiconductor device according to some embodiments, the first gate structure GS1 may further include a plurality of inner spacers 140_ISP.

The plurality of inner spacers 140_ISP may be disposed between the first sheet patterns NS1, and between the first lower pattern BP1 and the first sheet pattern NS1. An inner spacer 140_ISP may be disposed between the upper surface BP1_US of the first lower pattern and the lower surface NS1_BS of the first lowermost sheet pattern, and additional inner spacers 140_ISP may be disposed between the upper surface NS1_US of the first sheet pattern and the lower surface NS1_BS of an adjacent first sheet pattern, where both first sheet patterns face each other in the third direction D3.

The inner spacer 140_ISP is disposed between the inner gate structures INT1_GS1, INT2_GS1, INT3_GS1, and INT4_GS1 and the first source/drain pattern 150. In some embodiments, the number of inner spacers 140_ISP arranged in the third direction D3 is the same as the number of inner gate structures INT1_GS1, INT2_GS1, INT3_GS1, and INT4_GS1.

The inner spacer 140_ISP contacts with the inner gate structures INT1_GS1, INT2_GS1, INT3_GS1, and INT4_GS1. In some embodiments, the inner spacer 140_ISP prevents the inner gate structures INT1_GS1, INT2_GS1, INT3_GS1, and INT4_GS1 from contacting the first source/drain pattern 150.

The inner spacer 140_ISP may include silicon nitride (SiN), silicon oxynitride (SiON), silicon oxide (SiO₂), silicon oxycarbonitride (SiOCN), silicon boronitride (SiBN), silicon oxyboronitride (SiOBN), silicon oxycarbide (SiOC), or a combination thereof. The inner spacer 140_ISP may include a first side wall which faces the first source/drain pattern 150, and a second side wall which faces the inner gate structures INT1_GS1, INT2_GS1, INT3_GS1, and INT4_GS1. In FIG. 11, the first side wall of the inner spacer 140_ISP may entirely and directly contact the first source/drain pattern 150.

In FIG. 12, the semiconductor device according to some embodiments may further include a third epitaxial air gap 150_AG3 formed between the inner spacer 140_ISP and the first source/drain pattern 150. In an example, the third epitaxial air gap 150_AG3 directly contacts the first side wall of the inner spacer 140_ISP.

In some embodiments, one or more of the inner spacers 140_ISP may share a first side wall that directly contacts the first source/drain pattern 150.

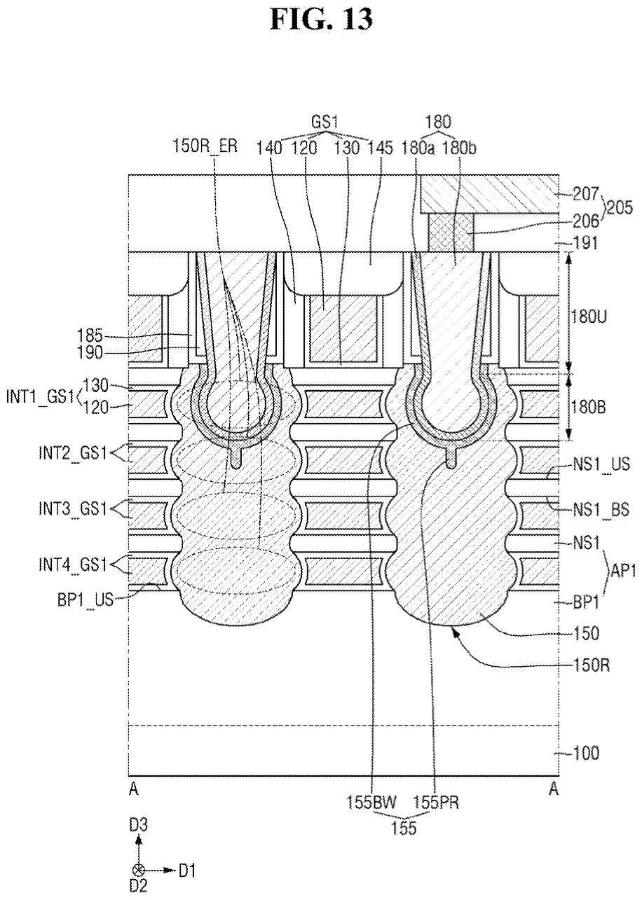

FIG. 13 is a diagram of a semiconductor device according to some embodiments of the present disclosure. Referring to FIG. 13, a first source/drain contact 180 may include an upper part 180U and a lower part 180B. In an embodiment, the upper part 180U of the first source/drain contact is disposed on the lower part 180B of the first source/drain contact. The upper part 180U of the first source/drain contact is directly connected to the lower part 180B of the first source/drain contact.

The lower part 180B of the first source/drain contact may have a bulge shape. For example, in the lower part 180B of the first source/drain contact 180, the width of the first source/drain contact 180 may increase in the first direction D1 and then decrease in the first direction D1 with distance from the upper surface of the first gate structure GS1. In some embodiments, in the lower part 180B of the first source/drain contact, the width of the first source/drain contact 180 may increase in the first direction D1 and then decrease in the first direction D1 with distance from the upper surface BP1_US of the first lower pattern. Additionally or alternatively, in lower part 180B of the first source/drain contact, the width of the first source/drain contact 180 may increase in the second direction D2 and then decrease in the second direction D2 with distance from the upper surface of the first gate structure GS1.

For example, the width of the lower part 180B of the first source/drain contact at a second height with respect to the upper surface BP1_US of the first lower pattern may be greater than the width of the lower part 180B of the first source/drain contact at a first height with respect to the upper surface BP1_US of the first lower pattern. The width of the lower part 180B of the first source/drain contact at the second height with respect to the upper surface BP1_US may be greater than the width of the lower part 180B of the first source/drain contact at a third height with respect to the upper surface BP1_US. The second height is greater than the first height and smaller than the third height.

The first contact silicide film 155 may wrap the lower part 180B of the first source/drain contact. For example, the first contact silicide film 155 may cover a bottom surface of the lower part 180B of the first source/drain contact as well as partially or fully cover lateral side(s) of the lower part 180B of the first source/drain contact. The lower part 180B of the first source/drain contact may be disposed in the first source/drain pattern 150.

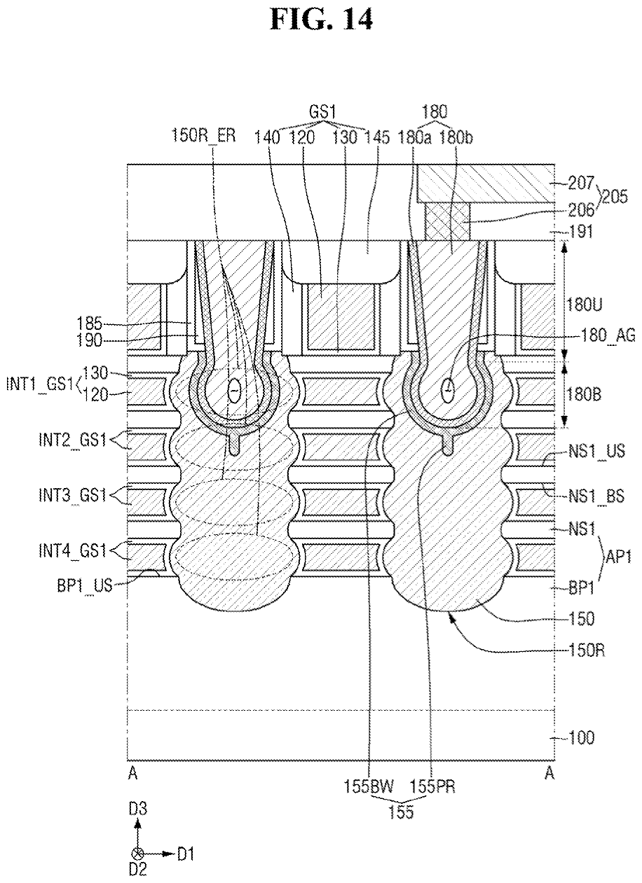

FIG. 14 is a diagram of a semiconductor device according to some embodiments of the present disclosure. Referring to FIG. 14, the semiconductor device according to some embodiments may further include a contact air gap 180_AG disposed in the first source/drain contact 180. For example, the contact air gap 180_AG may be disposed within the lower part 180B of the first source/drain contact.

The contact air gap 180_AG may be surrounded by the first source/drain contact 180. The contact air gap 180_AG may be disposed in the first source/drain filling film 180b. The contact air gap 180_AG may be surrounded by the first source/drain filling film 180b.

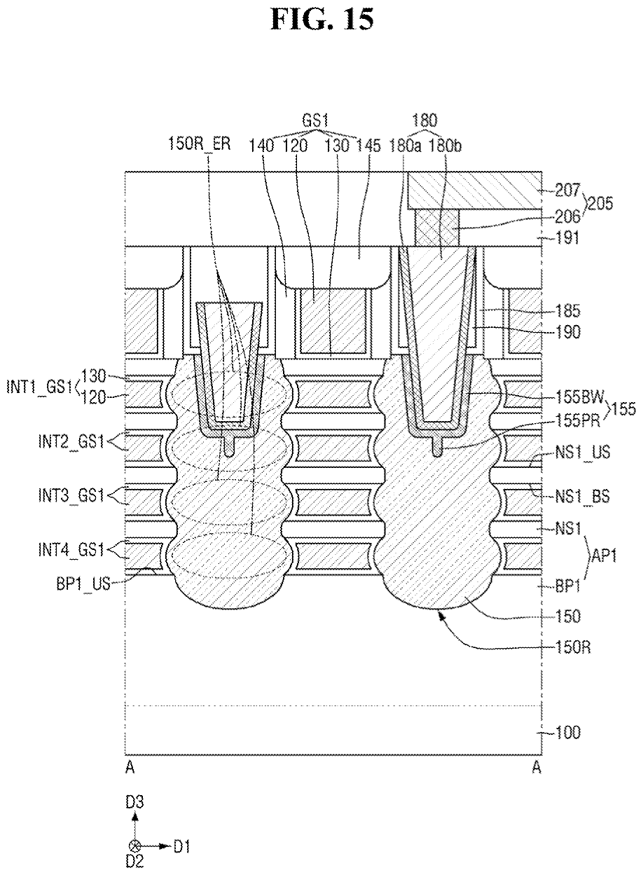

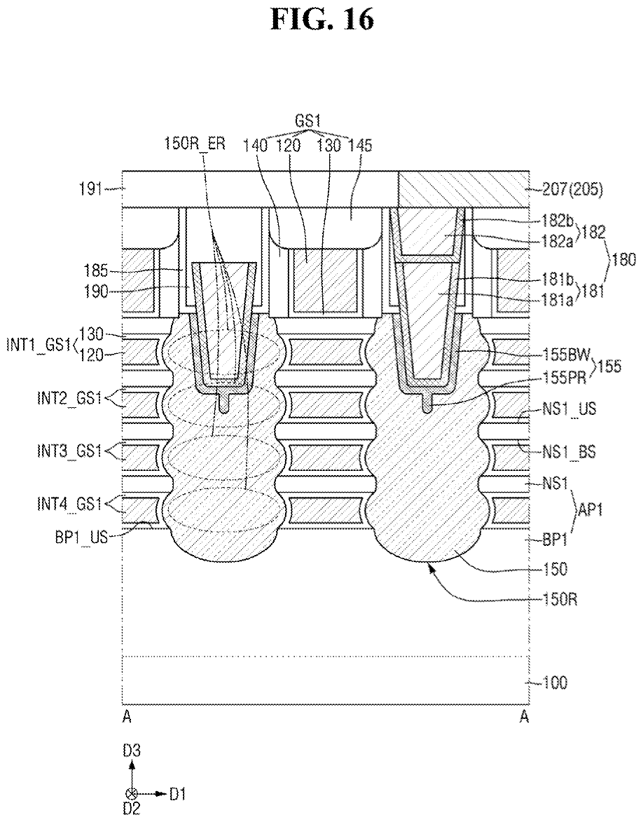

FIGS. 15 and 16 are diagrams of a semiconductor device according to some embodiments, respectively. Referring to FIG. 15, an upper surface of the first source/drain contact 180 that is not connected to the wiring structure 205 is disposed lower than the upper surface of the first gate capping pattern 145.

In at least some embodiments, the upper surface of the first source/drain contact 180 of the portion connected to the wiring structure 205 is disposed lower than the upper surface of the first source/drain contact 180 of the portion that is not connected to the wiring structure 205.

Referring to FIG. 16, in the semiconductor devices according to some embodiments, the first source/drain contacts 180 includes a lower source/drain contact 181 and an upper source/drain contact 182. The upper source/drain contact 182 is disposed on the lower source/drain contact 181. The upper source/drain contact 182 may be disposed in the portion connected to the wiring structure 205. In some embodiments, the upper source/drain contacts 182 are not be disposed in the portion that is not connected to the wiring structure 205.

The wiring line 207 may be connected to the first source/drain contact 180 without a wiring via (e.g., 206 of FIG. 2). For example, in some embodiments, the wiring line 207 may extend horizontally and directly contact the first source/drain contact 180 without a via portion or a vertical portion.

The lower source/drain contact 181 may include a lower source/drain barrier film 181a and a lower source/drain filling film 181b. The upper source/drain contact 182 may include an upper source/drain barrier film 182a and an upper source/drain filling film 182b. The lower source/drain contact 181 and the upper source/drain contact 182 may be made of a metal alloy, a conductive metal nitride, a conductive metal carbide, a conductive metal oxide, a conductive metal carbonitride, a two-dimensional (2D) material, or a combination thereof. In some embodiments, one or both of the lower source/drain contact 181 and the upper source/drain contact 182 may be a single film.

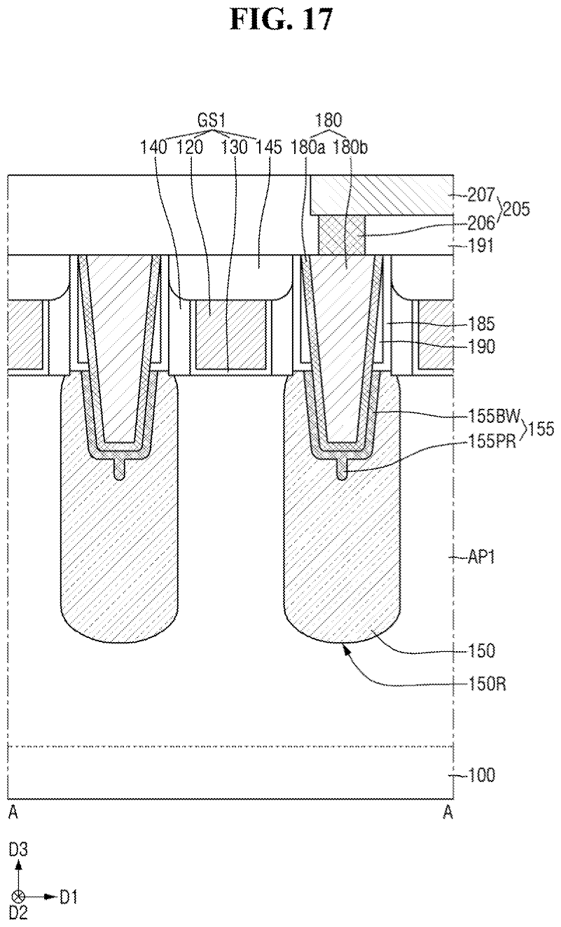

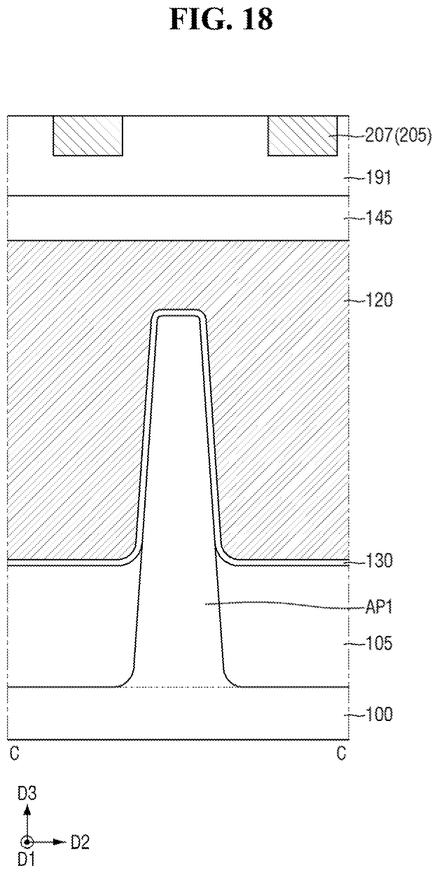

FIGS. 17 and 18 are diagrams of a semiconductor device according to some embodiments of the present disclosure. Referring to FIGS. 17 and 18, in some embodiments of the present disclosure, the first active pattern AP1 does not include the first sheet pattern (NS1 of FIG. 2).

The first active pattern AP1 may be a fin-type pattern. The first active pattern AP1, may be used as a channel region of a transistor including the first gate electrode 120.

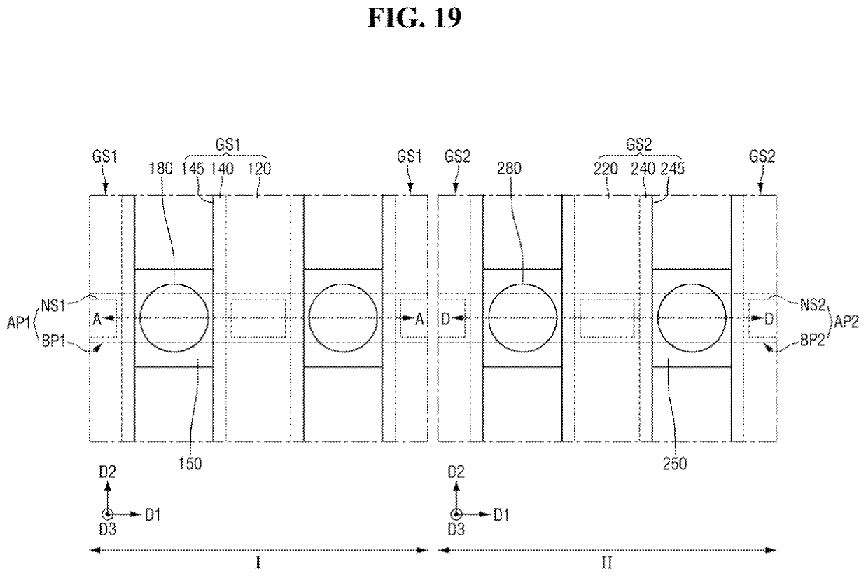

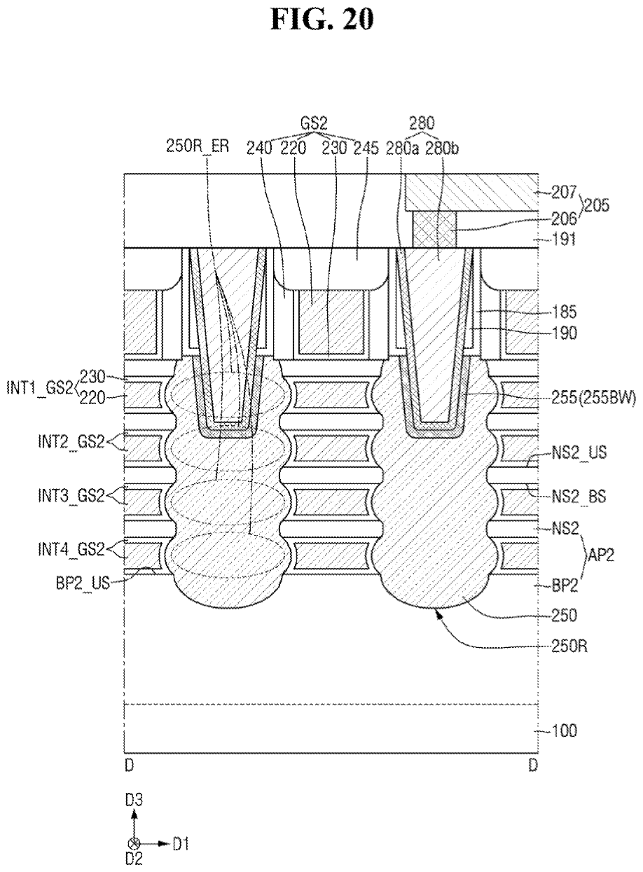

FIG. 19 is an plan view of a semiconductor device according to some embodiments of the present disclosure. FIG. 20 is a cross-sectional view taken along a line D-D of FIG. 19.

In some embodiments, the cross-sectional view taken along A-A of FIG. 19 may be the same as or similar to one of the cross-sectional views of FIGS. 2, and 7 to 14. In addition, the description for components represented in the first region I of FIG. 19 may be the same or similar to the description of corresponding components from FIGS. 1 to 14.

Referring to FIGS. 19 and 20, a semiconductor device according to some embodiments of the present disclosure may include a first active pattern AP1, a plurality of first gate structures GS1, a first source/drain pattern 150, a first source/drain contact 180, a second active pattern AP2, a plurality of second gate structures GS2, a second source/drain pattern 250, and a second source/drain contact 280.

The substrate 100 may include a first region I and a second region II. The first region I may be a region in which an NMOS is formed, and the second region II may be a region in which a PMOS is formed.

The first active pattern AP1, the plurality of first gate structures GS1, the first source/drain pattern 150 and the first source/drain contact 180 are disposed in the first region I of the substrate 100. The second active pattern AP2, the plurality of second gate structures GS2, the second source/drain pattern 250, and the second source/drain contact 280 are disposed on the second region II of the substrate 100.

The second active pattern AP2 may include a second lower pattern BP2 and a plurality of second sheet patterns NS2. The plurality of second sheet patterns NS2 are disposed on the upper surface BP2_US of the second lower pattern. The second sheet pattern NS2 includes an upper surface NS2_US and a lower surface NS2_BS which are opposite to each other in the third direction D3. The second lower pattern BP2 and the second sheet pattern NS2 may each include one of silicon or germanium, a group IV-IV compound semiconductor, a group III-V compound semiconductor, or a combination thereof. The second lower pattern BP2 may be a silicon lower pattern including silicon, and the second sheet pattern NS2 may be a silicon sheet pattern including silicon.

The plurality of second gate structures GS2 may be disposed on the substrate 100. The second gate structure GS2 may be disposed on the second active pattern AP2. The second gate structure GS2 may intersect the second active pattern AP2. The second gate structure GS2 may intersect the second lower pattern BP2. The second gate structure GS2 may wrap the second sheet patterns NS2. For example, the second gate structure GS2 may at least partially surround second sheet patterns NS2. The second gate structure GS2 may surround lateral sides of each of the second sheet patterns NS2.

The second gate structure GS2 may include a plurality of inner gate structures INT1_GS2, INT2_GS2, INT3_GS2, and INT4_GS2 disposed between the second sheet patterns NS2. For example, each of the plurality of inner gate structures may be disposed between a pair of second sheet patterns NS2 that are adjacent to each other in the third direction D3, and one of the inner gate structures such as INT4_GS2 may be disposed between the second lower pattern BP2 and the second sheet pattern NS2. The second gate structure GS2 may include, for example, a second gate electrode 220, a second gate insulating film 230, a second gate spacer 240, and a second gate capping pattern 245.

A second source/drain pattern 250 may be formed on the second active pattern AP2. The second source/drain pattern 250 may be formed on the second lower pattern BP2. The second source/drain pattern 250 may be connected to the second sheet pattern NS2. The second source/drain pattern 250 may be included in the source/drain of a transistor that uses the second sheet pattern NS2 as a channel region.

The second source/drain pattern 250 may be disposed in the second source/drain recess 250R. The second source/drain recess 250R may include a plurality of second width extension regions 250R_ER. A bottom surface of the second source/drain recess 250R may be defined by the second lower pattern BP2. Side walls of the second source/drain recess 250R may be defined by the second sheet pattern NS2 and the inner gate structures INT1_GS2, INT2_GS2, INT3_GS2, and INT4_GS2.

The second source/drain pattern 250 may contact the second gate insulating film 230 and the second lower pattern BP2 of the inner gate structures INT1_GS2, INT2_GS2, INT3_GS2, and INT4_GS2.

The second source/drain pattern 250 may include an epitaxial pattern. Embodiments of the second source/drain pattern 250 include a semiconductor material. The second source/drain pattern 250 may include silicon, silicon-germanium, or the like. The second source/drain pattern 250 may include p-type impurities. A p-type dopant of second source/drain pattern 250 may include boron (B). Although FIG. 20 illustrates the second source/drain pattern 250 as a single film, embodiments of the present disclosure are not necessarily limited thereto.

The second source/drain contact 280 is disposed on the second source/drain pattern 250. The second source/drain contact 280 is connected (e.g., electrically) to the second source/drain pattern 250. In some embodiments, the second source/drain contact 280 passes through the first interlayer insulating film 190 and the source/drain etch stop film 185, and may be connected to the second source/drain pattern 250.

The second source/drain contact 280 may include a second source/drain barrier film 280a and a second source/drain filling film 280b. The second source/drain filling film 280b is disposed on the second source/drain barrier film 280a.

A second contact silicide film 255 is disposed between the second source/drain contact 280 and the second source/drain pattern 250. The second contact silicide film 255 wraps the second source/drain contact 280 that penetrates into the second source/drain pattern 250. In some examples, the second contact silicide film 255 directly contacts the second source/drain contact 280 and the second source/drain pattern 250.

The second contact silicide film 255 may include a bowl region 255BW. Unlike the first contact silicide film 155, the second contact silicide film 255 may not include a protruding region (e.g., 155PR of FIG. 2). The second contact silicide film 255 includes a metal silicide material.

Accordingly, embodiments of the present disclosure include a semiconductor device, wherein one or more source/drain patterns of the semiconductor device include a silicide film with a protruding portion. In some examples, the protruding portion increases a contact area of a source/drain contact with the source/drain pattern, thereby forming a connection with increased reliability, and thereby increasing the reliability of the semiconductor device. Some embodiments of the semiconductor device include a protruding portion of silicide film that fills or partially fills an air gap within the source/drain pattern. which allows the silicide film to extend to a greater depth within the pattern and further increase the contact area. Accordingly, a semiconductor device of the present disclosure may have increased reliability and performance.

In concluding the detailed description, those skilled in the art will appreciate that many variations and modifications may be made to the embodiments described herein without departing from the principles of the present inventive concept. Aspects and features of some of the described embodiments may be combined with aspects and features of other described embodiments, for example. Therefore, the disclosed embodiments of the invention are used in a generic and descriptive sense only and not for purposes of limitation.

What is claimed is:

1. A semiconductor device comprising:
a substrate;
an active pattern disposed on the substrate and extending in a first direction;
a plurality of gate structures, wherein the plurality of gate structures is disposed on the active pattern and arranged in the first direction, wherein each gate structure of the plurality of gate structures includes a gate electrode and a gate insulating film, and wherein the gate electrode extends in a second direction that intersects the first direction;
a source/drain pattern disposed between adjacent gate structures of the plurality of gate structures;
a source/drain contact connected to the source/drain pattern; and
a contact silicide film disposed between the source/drain pattern and the source/drain contact,
wherein the contact silicide film includes a bowl region that wraps a lower portion of the source/drain contact, and a protruding region that protrudes from the bowl region of the contact silicide film in a third direction, wherein the third direction is orthogonal to the first and second directions.

2. The semiconductor device of claim 1, further comprising:
a first epitaxial air gap disposed in the source/drain pattern,
wherein the first epitaxial air gap directly contacts the protruding region of the contact silicide film.

3. The semiconductor device of claim 2, further comprising:
a second epitaxial air gap disposed in the source/drain pattern,
wherein the second epitaxial air gap is spaced apart from the first epitaxial air gap in the third direction.

4. The semiconductor device of claim 1, further comprising:
an epitaxial air gap disposed in the source/drain pattern,
wherein the epitaxial air gap is spaced part from the protruding region of the contact silicide film in the third direction.

5. The semiconductor device of claim 1, further comprising:
a contact air gap disposed in the source/drain contact.

6. The semiconductor device of claim 1,
wherein the source/drain contact includes a lower part and an upper part,
the upper part of the source/drain contact is disposed on the lower part of the source/drain contact, and
wherein a shape of the lower part of the source/drain contact bulges in the first direction.

7. The semiconductor device of claim 1,
wherein the active pattern includes a lower pattern that extends in the first direction and a plurality of sheet patterns, wherein the plurality of sheet patterns is arranged in the third direction and spaced apart from the lower pattern in the third direction,
wherein the gate structure includes an inner gate structure that includes portions disposed between the lower pattern and the sheet pattern, and between adjacent sheet patterns of the plurality of sheet patterns, and
wherein the inner gate structure includes the gate electrode and the gate insulating film.

8. The semiconductor device of claim 7,
wherein the source/drain pattern contacts the gate insulating film of the inner gate structure.

9. The semiconductor device of claim 7,
wherein the gate structure further includes one or more inner spacers disposed between the inner gate structure and the source/drain pattern, and wherein the one or more inner spacers contact the one or more portions of the inner gate structure, respectively.

10. The semiconductor device of claim 9, further comprising:
an epitaxial air gap disposed between the inner spacer and the source/drain pattern.

11. The semiconductor device of claim 1,
wherein the bowl region of the contact silicide film includes an inner side surface and an outer side surface,
the inner side surface contacts the source/drain contact,
the outer side surface contacts the source/drain pattern,
the inner side surface and the outer side surface each have a convex shape that bends towards the substrate, and
wherein the protruding region of the contact silicide film protrudes from the outer side surface of the bowl region of the contact silicide film.

12. A semiconductor device comprising:
an active pattern including a lower pattern which extends in a first direction, wherein the active pattern includes a plurality of sheet patterns, wherein each of the plurality of sheet patterns extends in a second direction, and is spaced apart from the lower pattern in a third direction;
a plurality of gate structures arranged in the first direction and disposed on the active pattern, wherein each of the plurality of gate structures includes a gate electrode and a gate insulating film, and wherein the gate electrode extends in the second direction;
a source/drain pattern disposed between adjacent gate structures of the plurality of gate structures and connected to the plurality of sheet patterns;
a source/drain contact connected to the source/drain pattern; and
a contact silicide film disposed between the source/drain pattern and the source/drain contact,
wherein, as apparent from a cross-sectional view, the contact silicide film includes a protruding region, and includes a first bowl region and a second bowl region, wherein the first bowl region and the second bowl region each branch from the protruding region of the contact silicide film,
the first bowl region of the contact silicide film and the second bowl region of the contact silicide film each extend in the third direction, and
wherein the source/drain contact is disposed between the first bowl region of the contact silicide film and the second bowl region of the contact silicide film.

13. The semiconductor device of claim 12,
wherein the protruding region of the contact silicide film extends in the third direction from a lowermost part of the source/drain contact proximate to the lower pattern.

14. The semiconductor device of claim 12, further comprising:
an epitaxial air gap disposed in the source/drain pattern,
wherein the epitaxial air gap directly contacts the protruding region of the contact silicide film.

15. The semiconductor device of claim 12, further comprising:
an epitaxial air gap disposed in the source/drain pattern,
wherein a portion of the source/drain pattern is disposed between the epitaxial air gap and the protruding region of the contact silicide film.

16. The semiconductor device of claim 12,
wherein the source/drain contact includes a lower part and an upper part,
the upper part of the source/drain contact is disposed on the lower part of the source/drain contact, and
wherein a shape of the lower part of the source/drain bulges in the first direction.

17. The semiconductor device of claim 12,
wherein the gate structure includes an inner gate structure including portions disposed between the lower pattern and the sheet pattern, and between adjacent sheet patterns of the plurality of sheet patterns,
wherein the inner gate structure includes the gate electrode and the gate insulating film, and
wherein the source/drain pattern contacts the gate insulating film of the inner gate structure.

18. A semiconductor device comprising:
a substrate;
a first active pattern that includes a first lower pattern and a plurality of first sheet patterns spaced apart from the first lower pattern in a vertical direction corresponding to a thickness direction of the substrate;
a second active pattern that includes a second lower pattern and a plurality of second sheet patterns spaced apart from the second lower pattern in the vertical direction;
a plurality of first gate structures disposed on the first lower pattern and arranged in a first horizontal direction;
a plurality of second gate structures disposed on the second lower pattern and arranged in the first horizontal direction;
a first source/drain pattern disposed between adjacent gate structures of the first gate structures, and wherein the first source/drain pattern comprises n-type impurities;
a second source/drain pattern disposed between adjacent gate structures of the second gate structures, and wherein the second source/drain pattern comprises p-type impurities;
a first source/drain contact connected to the first source/drain pattern;
a second source/drain contact connected to the second source/drain pattern;
a first contact silicide film disposed between the first source/drain pattern and the first source/drain contact;
a second contact silicide film disposed between the second source/drain pattern and the second source/drain contact; and
a first epitaxial air gap disposed in the first source/drain pattern, wherein the first epitaxial air gap contacts the first contact silicide film,
and wherein the first contact silicide film includes a bowl region which extends along a profile of the first source/drain contact, and a protruding region which protrudes from the bowl region of the first contact silicide film in the vertical direction.

19. The semiconductor device of claim 18,
wherein the first epitaxial air gap contacts the protruding region of the first contact silicide film, and
wherein the first epitaxial air gap is disposed below the protruding region of the first contact silicide film.

20. The semiconductor device of claim 18, further comprising:
a second epitaxial air gap disposed in the first source/drain pattern,
wherein the second epitaxial air gap is spaced apart from the first epitaxial air gap.
